(19) United States
(12) Patent Application Publication
(10) Pub. No.: US 2026/0171164 A1
(43) Pub. Date: Jun. 18, 2026

(54) SENSE AMPLIFIER REDUCING CAPACITIVE COUPLING EFFECT AND A SENSE CIRCUIT AND A MEMORY DEVICE COMPRISING THE SAME

(71) Applicant: EMEMORY TECHNOLOGY INC., HSINCHU (TW)

(72) Inventors: CHIA-FU CHANG, Hsinchu County (TW); YOU-RUEI CHUANG, HSINCHU COUNTY (TW)

(21) Appl. No.: 19/416,652

(22) Filed: Dec. 11, 2025

Related U.S. Application Data
(60) Provisional application No. 63/734,217, filed on Dec. 16, 2024.

(51) Int. Cl. G11C 16/28; G11C 5/14; G11C 16/30; G11C 16/34

(52) U.S. Cl. CPC G11C 16/28; G11C 5/146; G11C 16/30; G11C 16/3418

(57) ABSTRACT

A sense amplifier is provided. The sense amplifier includes first through third transistors, a bias circuit, and a voltage coupling circuit. The first transistor is coupled between a first power terminal and a first node. The second transistor is coupled between the first and second nodes, and has a gate receiving a reference voltage. The third transistor is coupled between the first and third nodes, and has a gate receiving a data voltage. The bias circuit couples the second and third nodes to a second power terminal. The voltage coupling circuit is coupled between the first node and the gate of the second transistor, and provides a first voltage to the gate of the second transistor. The first voltage is negatively correlated to a voltage at the first node. The gate of the second transistor has a resistor-capacitor loading smaller than that of the gate of the third transistor.

### PRIORITY CLAIM AND CROSS-REFERENCE

The present application claims priority to U.S. Provisional Patent Application Ser. No. 63/734,217, filed on Dec. 16, 2024, which is incorporated by reference herein in its entirety.

### BACKGROUND

In non-volatile memory (NVM) technologies, the stored information is encoded as variations in resistance, threshold voltage, or charge state. The sense amplifiers are designed to accurately and quickly convert these subtle physical changes into robust digital signals for further processing. The input from the memory cell is fed into one input terminal of the sense amplifier, and the reference signal is inputted into the other input terminal. When activated, the sense amplifier amplifies the difference between the two input terminals, driving the output to a distinct logic level that represents the storage state (e.g., bit 0 or bit 1) in the memory cell. This differential sensing approach enhances noise immunity and improves read accuracy, especially important given the small signal margins in scaled memory technologies.

### SUMMARY

One aspect of the present disclosure provides a sense amplifier applicable to a non-volatile memory (NVM) device. The sense amplifier includes a first transistor, a second transistor, a third transistor, a bias circuit, and a voltage coupling circuit. The first transistor is coupled between a first power terminal and a first node. A gate of the first transistor is configured to receive an enable signal, and the first transistor is switched on by the enable signal to generate a common voltage at the first node. The second transistor is coupled between the first node and a second node. A gate of the second transistor is configured to receive the reference voltage. The third transistor is coupled between the first node and a third node. A gate of the third transistor is configured to receive a data voltage. The bias circuit is configured to couple the second node and the third node to a second power terminal and to generate a sense output data according to the reference voltage and the data voltage. The voltage coupling circuit is coupled between the first node and the gate of the second transistor, and is configured to provide a first voltage to the gate of the second transistor. During a sensing period of the non-volatile memory device, a resistor-capacitor loading of the second transistor seen from the gate of the second transistor is smaller than a resistor-capacitor loading of the third transistor seen from the gate of the third transistor. The first voltage is negatively correlated to the common voltage.

One aspect of the present disclosure provides a sense circuit applicable to a NVM device. The sense circuit includes a plurality of stages of sense amplifiers, a plurality of data lines, and a reference voltage line. The plurality of data lines are respectively coupled to the plurality of sense amplifiers. The reference voltage line is configured to provide a reference voltage. Each sense amplifier includes a first transistor, a second transistor, a third transistor, a bias circuit, and a voltage coupling circuit. The first transistor is coupled between a first power terminal and a first node. A gate of the first transistor is configured to receive an enable signal, and the first transistor is switched on by the enable signal to generate a common voltage at the first node. The second transistor is coupled between the first node and a second node. A gate of the second transistor is coupled to the reference voltage line. The third transistor is coupled between the first node and a third node. A gate of the third transistor is coupled to a corresponding one of the plurality of data lines. The bias circuit is configured to couple the second node and the third node to a second power terminal and to generate a sense output data according to the reference voltage and the data voltage. The voltage coupling circuit is coupled between the first node and the gate of the second transistor, and is configured to provide a first voltage to the gate of the second transistor. The first voltage is negatively correlated to the common voltage.

One aspect of the present disclosure provides a NVM device. The NVM device includes a memory array, the sense circuit mentioned above (i.e., the sensing circuit having the plurality of stages of sense amplifiers, the plurality of data lines, and the reference voltage line), and a bit line selector. The memory array includes a plurality of bit lines. The bit line selector is configured to select a set of bit lines from the plurality of bit lines to respectively couple to the plurality of data lines.

The proposed sense amplifier, sense circuit, and NVM device are capable of stabling the voltage on the reference voltage line to prevent misjudgment to storage state of the memory cell. Moreover, the proposed sense amplifier, sense circuit, and NVM device have small overall areas.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a functional block diagram of a non-volatile memory (NVM) device, according to some embodiments of the present disclosure.

FIG. 2 is a circuit schematic of the sense circuit, according to some comparative embodiments.

FIG. 3 is a circuit schematic of a sense amplifier, according to some embodiments of the present disclosure.

FIG. 4 is a circuit schematic of a sense amplifier, according to some embodiments of the present disclosure.

FIG. 5 is a circuit schematic of a sense amplifier, according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the present disclosure may repeat reference numerals and/or letters in the various examples. This repetition is for the purpose of simplicity and clarity and does not in itself dictate a relationship between the various embodiments and/or configurations discussed.

Further, it will be understood that when an element is referred to as being “connected to” or “coupled to” another element, it may be directly connected to or coupled to the other element, or intervening elements may be present.

Moreover, spatially relative terms, such as “below,” “above,” “left,” “right,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

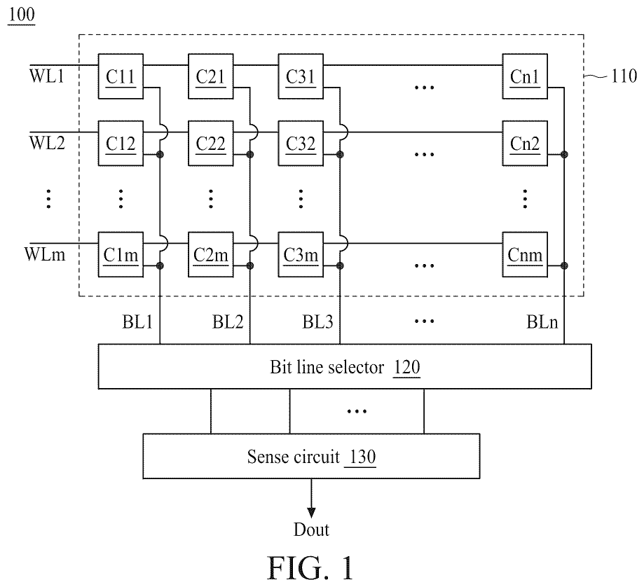

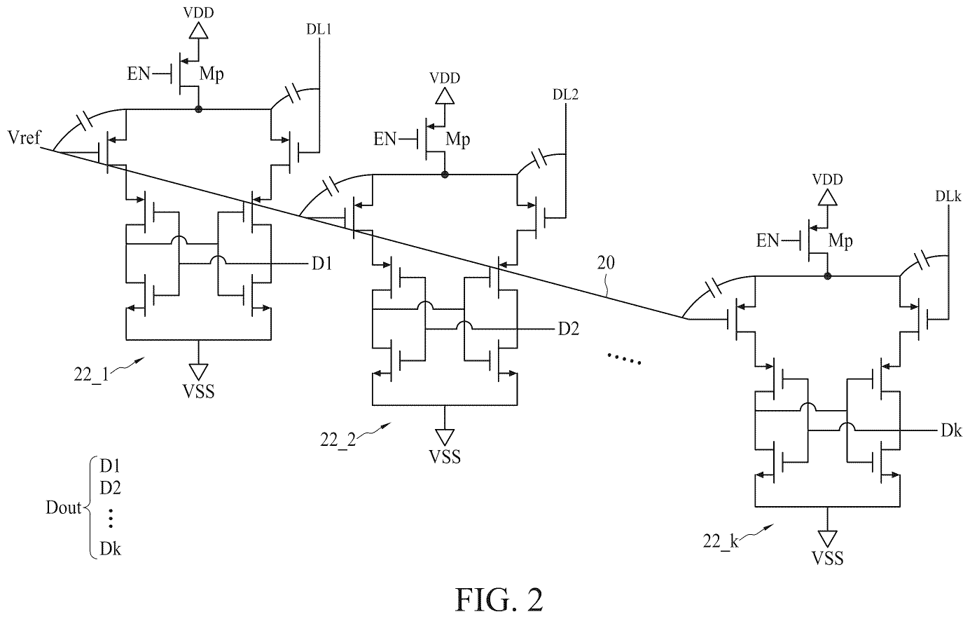

FIG. 1 is a functional block diagram of a non-volatile memory (NVM) device 100, according to some embodiments of the present disclosure. FIG. 2 is a circuit schematic of the sense circuit 130, according to some comparative embodiments. The NVM device 100 includes a memory array 110, a bit line selector 120, and the sense circuit 130. The memory array includes word lines WL1 to WLm, bit lines BL1 to BLn, and memory cells C11 to Cnm having a number of “m×n, where m and n are positive integers. The word line WL1 is coupled to a first row of memory cells C11 to Cn1; and the word line WL2 is coupled to a second row of memory cells C12 to Cn2, and so on. The bit line BL1 is coupled to a first column of memory cells C11 to C1m; and the bit line BL2 is coupled to a second column of memory cells C21 to C2m, and so on. The bit line selector 120 is coupled to the bit lines BL1 to BLn. The sense circuit 130 includes data lines DL1 to DLk, a reference voltage line 20, and k stages of sense amplifiers 22_1 to 22_k, where k is a positive integer smaller than n. The sense circuit 130 is coupled to the bit line selector 120 through the data lines DL1 to DLk. The read operation of the NVM device 100 may include charging periods and

sensing periods, which are alternatively arranged. In each charging period of the NVM device 100, the bit line selector 120 can select a set of bit lines (e.g., k bit lines) from the bit lines BL1 to BLn to connect to the data lines DL1 to DLk of the sense circuit 130. Then, a set of selected memory cells (e.g., k memory cells) in the selected row can charge the set of bit lines.

In each sensing period of the NVM device 100, the sense amplifiers 22_1 to 22_k are enabled by an enable signal EN. The sense amplifiers 22_1 to 22_k may determine the storage state (e.g., bit 0 or bit 1) of the selected memory cells, so as to generate output data D1 to Dk. The sense circuit 130 can combine the output data D1 to Dk to form k-bit output data Dout. In some embodiments, the transition of the enable signal EN may indicate the start or the end of the sensing period.

For example, in a first charging period, k selected memory cells in the selected row charge the bit lines BL1 to BLk, which are connected to the data lines DL1 to DLk; then, in a first sensing period, the sense circuit 130 can generate the output data Dout based on the data voltages on the data lines DL1 to DLk. As another example, in a second charging period, another k selected memory cells in the selected row charge the bit lines BL(k+1) to BL2k, which are connected to the data lines DL1 to DLk; then, the sense circuit 130 can generate another k-bit output data Dout based on the data voltages on the data lines DL1 to DLk. In an example that n is 120 and k is 40, the sense circuit 130 may take three sensing periods to read out a row of memory cells.

During the sensing period, the transistor Mp of each of the sense amplifiers 22_1 to 22_k is switched on by the enable signal EN. The conducted transistors Mp provide the high voltage VDD into the sense amplifiers 22_1 to 22_k, so that the sense amplifiers 22_1 to 22_k can compare the data voltages on the data lines DL1 to DLk with the reference voltage Vref on the reference voltage line 20 to generate the output data D1 to Dk. For example, if the data voltage on the data line DL1 has a first level (e.g., a high level) higher than the reference voltage Vref, the output data D1 will be the low voltage VSS representing bit 1; if the data voltage on the data line DL1 has a second level (e.g., the low level) lower than the reference voltage Vref, the output data D1 will be the high voltage VDD representing bit 0.

However, when the transistors Mp are switched on, a rapid voltage increase occurs at the drain of each transistor Mp, which raises the reference voltage Vref and the data voltages on the data lines DL1 to DLk. This capacitive coupling effect is induced by the parasitic capacitor between the drain of the transistor Mp and the reference voltage line 20 as well as the parasitic capacitor between the drain of the transistor Mp and each of the data lines DL1 to DLk. Moreover, the resistor-capacitor (RC) loading on the reference voltage line 20 is lower than the RC loading of each of the data lines DL1 to DLk during the sensing period, as the data lines DL1 to DLk are connected to bit lines, each of which may be connected to more than a hundred of memory cells. Therefore, the reference voltage line 20 may be more affected by the capacitive coupling effect. For example, the reference voltage Vref may be coupled to be higher than the first level (e.g., the high level) of the data voltage, causing the corresponding output data being maintained at the low voltage VSS representing bit 1. Therefore, compensation means are required for mitigating the capacitive coupling effect caused by the transistor Mp to prevent the sense amplifiers 22_1 to 22_k from misjudging the storage state of the memory cells.

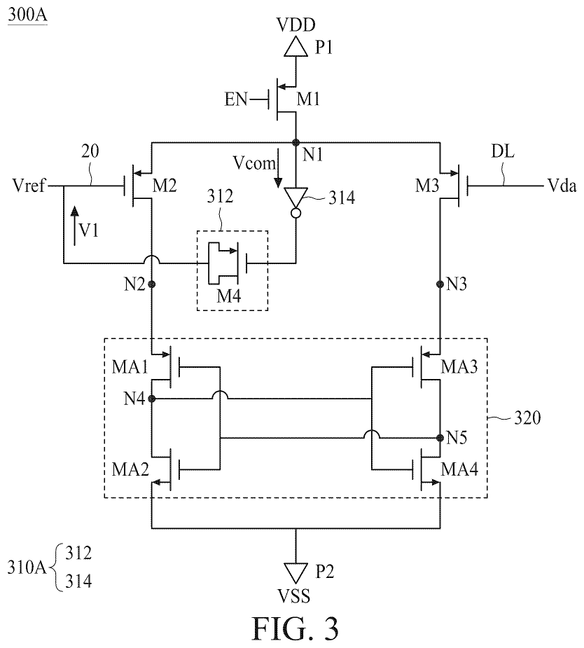

FIG. 3 is a circuit schematic of a sense amplifier 300A, according to some embodiments of the present disclosure. The sense circuit 130 may include a plurality of stages of the sense amplifier 300A. For example, one implementation of the sense circuit 130 may be realized by replacing each of the sense amplifiers 22_1 to 22_k of FIG. 2 with the sense amplifier 300A. The sense amplifier 300A includes transistors M1 to M3, a voltage coupling circuit 310A, and a bias circuit 320.

Each of the transistors M1 to M3 includes a source, a drain, and a gate. The source of the transistor M1 is coupled to a first power terminal P1 providing the high voltage VDD; the drain of the transistor M1 is coupled to a first node N1; and the gate of the transistor M1 is configured to receive the enable signal EN. The source of the transistor M2 is coupled to the first node N1; the drain of the transistor M2 is coupled to a second node N2; and the gate of the transistor M2 is coupled to the reference voltage line 20 providing the reference voltage Vref. The source of the transistor M3 is coupled to the first node N1; the drain of the transistor M3 is coupled to a third node N3; and a gate of the transistor M3 is coupled to the data line DL (e.g., one of the data lines DL1 to DLk of FIG. 2) to receive the data voltage Vda. In some embodiments, the transistors M1, M2, and M3 are P-type transistors, but this disclosure is not limited thereto.

One of the second node N2 and the third node N3 may be the output terminal of the sense amplifier 300A used to generate the output data (e.g., one of the output data D1 to Dk of FIG. 2). The gates of the transistors M2 and M3 can be regard as input terminals of the sense amplifier 300A.

The voltage coupling circuit 310A is coupled between the first node N1 and the gate of the transistor M2. The voltage coupling circuit 310A can provides a first voltage V1 to the gate of the transistor M2 to adjust the reference voltage Vref received by the transistor M2. The first voltage V1 is negatively correlated to a common voltage Vcom at the first node N1. For example, when the common voltage Vcom increases, the first voltage V1 decreases; and when the common voltage Vcom decreases, the first voltage V1 increases.

The voltage coupling circuit 310A includes a capacitor 312 and an inverter 314. An input terminal of the inverter is coupled to the first node N1. The capacitor 312 is coupled between an output terminal of the inverter 314 and the gate of the transistor M2. In some embodiments, the capacitor 312 includes a metal-oxide-semiconductor (MOS) capacitor. The MOS capacitor may be realized by a transistor M4 including a source, a drain, and a gate. The source and drain of the transistor M4 are coupled to the gate of the transistor M2, while the gate of the transistor M4 is coupled to the output terminal of the inverter 314. Alternatively, the source and drain of the transistor M4 is coupled to the output terminal of the inverter 314, while the gate of the transistor M4 is coupled to the gate of the transistor M2. In some embodiments, the transistor M4 is a P-type transistor, but this disclosure is not limited thereto.

The bias circuit 320 can couple the second node N2 and the third node N3 to a second power terminal P2 providing the low voltage VSS. In some embodiments, the bias circuit 320 includes a latch circuit configured to latch voltages of the second node N2 and the third node N3, where the latch circuit includes transistors MA1, MA2, MA3, and MA4. Each of the transistors MA1, MA2, MA3, and MA4 includes a source, a drain, and a gate. The transistors MA1 and MA2 are coupled in series between the second node N2 and the second power terminal P2. The transistor MA3 and MA4 are coupled in series between the third node N3 and the second power terminal P2. The gates of the transistors MA3 and MA4 are coupled to a fourth node N4 between the transistors MA1 and MA2. The gates of the transistors MA1 and MA2 are coupled to a fifth node N5 between the transistors MA3 and MA4. In some embodiments, the transistors MA1 and MA3 are P-type transistors, and the transistors MA2 and MA4 are N-type transistors, but this disclosure is not limited thereto.

When the enable signal EN switches on the transistor M1 at the start of the sensing period, the common voltage Vcom may rapidly increase, pulling up the reference voltage Vref and the data voltage Vda because of the capacitive coupling effect caused by the parasitic capacitors. It is noted that, during the sensing period, the reference voltage line 20 may have the RC loading that is smaller than the RC loading of the data line DL, as the data line DL is connected to a bit line, which may be connected to more than a hundred of memory cells. Therefore the magnitude of the reference voltage Vref may be more affected by the common voltage Vcom. In other words, during the sensing period, the RC loading of the transistor M2 seen from the gate of the transistor M2 may be smaller than the RC loading of the transistor M3 seen from the gate of the transistor M3. The inverter 314 outputs the inversed common voltage Vcom, which is then coupled to the gate of the transistor M2 as the first voltage V1 by the capacitive coupling effect caused by the capacitor 312. The first voltage V1 negatively correlated to the common voltage Vcom can mitigate the increase on the reference voltage Vref, so as to make the increase on the reference voltage Vref and the increase on the data voltage Vda to be substantially equal. As a result, it is ensured that the storage state of the memory cell will not be misjudged.

The MOS capacitor is used to compensate for the capacitive coupling effect induced by the parasitic capacitor. In order to generate a coupling effect equivalent to that caused by the parasitic capacitor, the MOS capacitor may be realized by the transistor M4, and the size of the transistor M4 may be equal to the size of the transistor M2. Furthermore, to achieve effective compensation, the capacitance of the MOS capacitor is positively correlated to the voltage difference between the gate and the source/drain thereof. The inversed common voltage Vcom outputted by the inverter 314 may be the low voltage VSS (e.g., the ground voltage), which may be much lower than the reference voltage Vref. Therefore, even the transistor M4 with small area can produce sufficient capacitance for generating the first voltage V1.

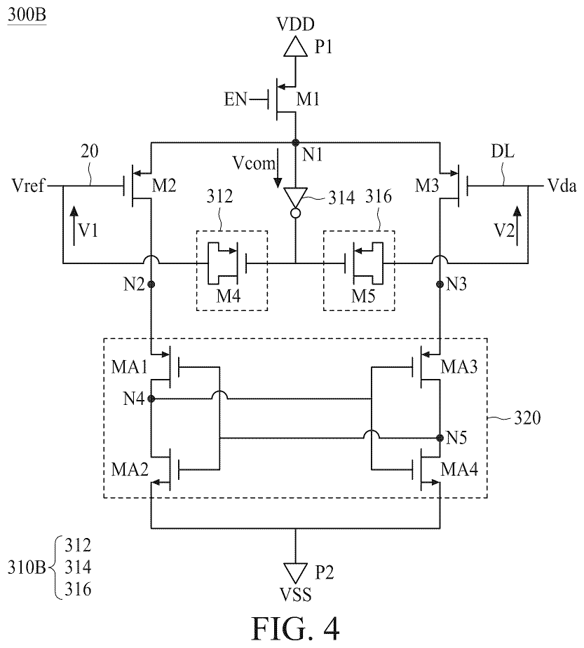

FIG. 4 is a circuit schematic of a sense amplifier 300B, according to some embodiments of the present disclosure. The sense circuit 130 may include a plurality of stages of the sense amplifier 300B. For example, one implementation of the sense circuit 130 may be realized by replacing each of the sense amplifiers 22_1 to 22_k of FIG. 2 with the sense amplifier 300B. The sense amplifier 300B of FIG. 4 is similar to the sense amplifier 300A of FIG. 3; therefore, only the difference between them are described below.

The sense amplifier 300B includes a voltage coupling circuit 310B. The voltage coupling circuit 310B includes a capacitor 312, an inverter 314, and a capacitor 316. The voltage coupling circuit 310B can provide the first voltage V1 to the gate of the transistor M2, and provide a second voltage V2 to the gate of the transistor M3. The first voltage and the second voltage are used to respectively adjust the reference voltage Vref received by the transistor M2 and the data voltage Vda received by the transistor M3. The first voltage V1 and the second voltage V2 are negatively correlated to the common voltage Vcom at the first node N1. For example, when the common voltage Vcom increases, the first voltage V1 and the second voltage V2 decrease; and when the common voltage Vcom decreases, the first voltage V1 and the second voltage V2 increase.

The capacitor 312 and the inverter 314 of FIG. 4 are similar to those described in FIG. 3; therefore, the detailed descriptions thereof are omitted. The capacitor 316 is coupled between the output terminal of the inverter 314 and the gate of the transistor M3. In some embodiments, the capacitor 316 includes a metal-oxide-semiconductor (MOS) capacitor. The MOS capacitor may be realized by a transistor M5 including a source, a drain, and a gate. The source and drain of the transistor M5 are coupled to the gate of the transistor M3, while the gate of the transistor M5 is coupled to the output terminal of the inverter 314. Alternatively, the source and drain of the transistor M5 is coupled to the output terminal of the inverter 314, while the gate of the transistor M5 is coupled to the gate of the transistor M3. In some embodiments, the transistor M5 is a P-type transistor, but this disclosure is not limited thereto. In some embodiments, the size of the transistor M5 may be equal to the size of the transistor M3.

The inverter 314 outputs the inversed common voltage Vcom. The inverse version of the common voltage Vcom is then coupled to the gate of the transistor M2 as the first voltage V1, and to the gate of the transistor M3 as the second voltage V2. The first voltage V1 and the second voltage V2 mitigate the increase on the reference voltage Vref and the data voltage Vda. Since the reference voltage line 20 may have a RC loading that is smaller than a RC loading of the data line DL, the capacitance of the capacitor 312 may be smaller than or equal to that of the capacitor 316. In other words, the width-to-length ratio of the transistor M4 may be smaller than or equal to that of the transistor M5. Therefore, when the common voltage Vcom rapidly increases, the increase on the reference voltage Vref and the increase on the data voltage Vda are adjusted to be substantially equal, ensuring that the storage state of the memory cell will not be misjudged.

Due the RC loading on the reference voltage line 20 and the signal line carrying the enable signal EN, the sense amplifiers in the later stages see the reference voltage Vref and/or the data voltage Vda coupled to higher levels. Therefore, when applying the sense amplifier 300A/300B to the sense circuit 130, the capacitance of the capacitor 312 in the sense amplifier 300A/300B of an i-th stage may be smaller than that of the capacitor 312 in the sense amplifier 300A/300B of an j-th stage, where i and j are positive integers and “i<j<k. Similarly, the capacitance of the capacitor 316 in the sense amplifier 300A/300B of the i-th stage may be smaller than that of the capacitor 316 in the sense amplifier 300A/300B of the j-th stage. The bias circuit 320 may be realized by various type of latch circuits having more

or less transistors than the latch circuit shown in FIG. 3 and FIG. 4. For example, the transistors MA1 and MA3 may be omitted. In addition, the bias circuit 320 is not limited to be realized by the latch circuit.

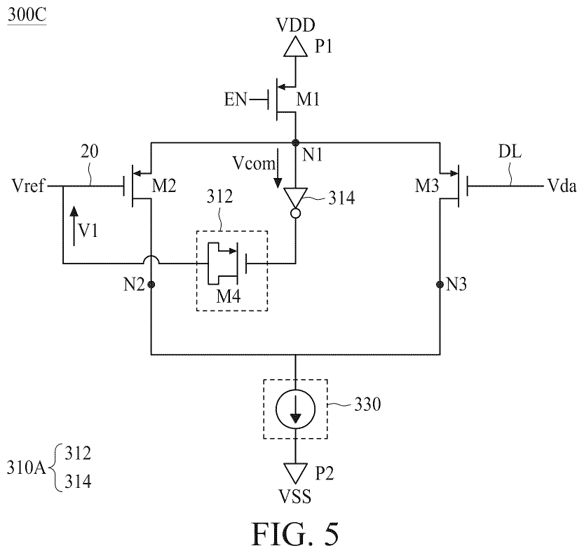

FIG. 5 is a circuit schematic of a sense amplifier 300C, according to some embodiments of the present disclosure. The sense circuit 130 may include a plurality of stages of the sense amplifier 300C. For example, one implementation of the sense circuit 130 may be realized by replacing each of the sense amplifiers 22_1 to 22_k of FIG. 2 with the sense amplifier 300C. The sense amplifier 300C of FIG. 5 is similar to the sense amplifier 300A of FIG. 3; therefore, only the difference between them are described below.

The sense amplifier 300C includes a bias circuit 330. The bias circuit 330 is used to couple the second node N2 and the third node N3 to the second power terminal P2. The bias circuit 330 includes a current source. A first terminal of the current source is coupled to the second node N2 and the third node N3. A second terminal of the current source is coupled to the second power terminal P2. The current source may have a circuit structure simpler than that of the latch circuits shown in FIG. 3 and FIG. 4, thereby reducing the overall circuit area of the sense amplifier 300C. It is noted that the voltage coupling circuit 310A of the sense amplifier 300C may be replaced by the voltage coupling circuit 310B of FIG. 4 without departing from the scope of the present disclosure.

Accordingly, the sense amplifiers provided in this disclosure can mitigate the capacitive coupling effect to the reference voltage line 20, thereby stabilizing the reference voltage Vref to prevent misjudgment to the storage state of memory cell. The sense amplifiers provided in this disclosure also have compact circuit structures as the voltage coupling circuit has a small overall area.

As used herein, the terms “substantially” are used to describe and account for small variations. When used in combination with an event or circumstance, the terms can refer to instances in which the event or circumstance occurs precisely as well as instances in which the event or circumstance occurs to a close approximation. As used herein with respect to a given value or range, the term “substantially” generally means within ±10%, ±5%, ±1%, or ±0.5% of the given value or range. Ranges can be expressed herein as from one endpoint to another endpoint or between two endpoints. All ranges disclosed herein are inclusive of the endpoints, unless specified otherwise. In addition, when referring to numerical values or characteristics as “substantially” the same, the term can refer to the values lying within ±10%, ±5%, ±1%, or ±0.5% of an average of the values.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A sense amplifier applicable to a non-volatile memory device, comprising:
a first transistor, coupled between a first power terminal and a first node, wherein a gate of the first transistor is configured to receive an enable signal, and the first transistor is switched on by the enable signal to generate a common voltage at the first node;
a second transistor, coupled between the first node and a second node, wherein a gate of the second transistor is configured to receive a reference voltage;
a third transistor, coupled between the first node and a third node, wherein a gate of the third transistor is configured to receive a data voltage ;
a bias circuit, configured to couple the second node and the third node to a second power terminal and to generate a sense output data according to the reference voltage and the data voltage; and
a voltage coupling circuit, coupled between the first node and the gate of the second transistor, and configured to provide a first voltage to the gate of the second transistor, wherein the first voltage is negatively correlated to the common voltage,
wherein during a sensing period of the non-volatile memory device, a resistor-capacitor loading of the second transistor seen from the gate of the second transistor is smaller than a resistor-capacitor loading of the third transistor seen from the gate of the third transistor.

2. The sense amplifier of claim 1, wherein the voltage coupling circuit comprises:
an inverter, comprising an input terminal coupled to the first node; and
a first capacitor, coupled between an output terminal of the inverter and the gate of the second transistor.

3. The sense amplifier of claim 2, wherein the first capacitor comprises a first MOS capacitor comprising a fourth transistor, wherein a source of the fourth transistor and a drain of the fourth transistor are coupled to the gate of the second transistor, and a gate of the fourth transistor is coupled to the output terminal of the inverter, and a size of the fourth transistor is equal to a size of the second transistor.

4. The sense amplifier of claim 3, wherein the voltage coupling circuit is further coupled between the first node and the gate of the third transistor, and is further configured to provide a second voltage to the gate of the third transistor, wherein the second voltage is negatively correlated to the common voltage at the first node.

5. The sense amplifier of claim 4, wherein the voltage coupling circuit further comprises:
a second capacitor, coupled between the output terminal of the inverter and the gate of the third transistor.

6. The sense amplifier of claim 5, wherein the second capacitor comprises a second MOS capacitor comprising a fifth transistor, wherein a source of the fifth transistor and a drain of the fifth transistor are coupled to the gate of the third transistor, and a gate of the fifth transistor is coupled to the output terminal of the inverter, and a size of the fifth transistor is equal to a size of the third transistor.

7. The sense amplifier of claim 6, wherein a width-to-length ratio of the fourth transistor is greater than or equal to a width-to-length ratio of the fifth transistor.

8. The sense amplifier of claim 1, wherein the bias circuit comprises a latch circuit configured to latch voltages of the second node and the third node.

9. The sense amplifier of claim 1, further comprising a parasitic capacitor coupled between a drain of the first transistor and the gate of the second transistor, and the parasitic capacitor inducing a capacitive coupling effect when the first transistor is switched on.

10. A sense circuit applicable to a non-volatile memory device, comprising:
a plurality of stages of sense amplifiers;
a plurality of data lines, respectively coupled to the plurality of sense amplifiers; and
a reference voltage line, configured to provide a reference voltage,
wherein each sense amplifier comprises:
a first transistor, coupled between a first power terminal and a first node, wherein a gate of the first transistor is configured to receive an enable signal, and the first transistor is switched on by the enable signal to generate a common voltage at the first node;
a second transistor, coupled between the first node and a second node, wherein a gate of the second transistor is coupled to the reference voltage line;
a third transistor, coupled between the first node and a third node, wherein a gate of the third transistor is coupled to a corresponding one of the plurality of data lines;
a bias circuit, configured to couple the second node and the third node to a second power terminal and to generate a sense output data according to the reference voltage and a data voltage; and
a voltage coupling circuit, coupled between the first node and the gate of the second transistor, and configured to provide a first voltage to the gate of the second transistor, wherein the first voltage is negatively correlated to the common voltage.

11. The sense circuit of claim 10, wherein during a sensing period of the non-volatile memory device, the reference voltage line has a resistor-capacitor loading smaller than a resistor-capacitor loading of the corresponding one of the plurality of data lines.

12. The sense circuit of claim 10, wherein the voltage coupling circuit comprises:
an inverter, comprising an input terminal coupled to the first node; and
a first capacitor, coupled between an output terminal of the inverter and the gate of the second transistor.

13. The sense circuit of claim 12, wherein the first capacitor of the sense amplifier of an i-th stage has capacitance smaller than that of the first capacitor of the sense amplifier of a j-th stage, wherein i and j are positive integers and i is smaller than j.

14. The sense circuit of claim 12, wherein the first capacitor comprises a MOS capacitor comprising a fourth transistor, wherein a source of the fourth transistor and a drain of the fourth transistor are coupled to the gate of the second transistor, and a gate of the fourth transistor is coupled to the output terminal of the inverter, and a size of the fourth transistor is equal to a size of the second transistor.

15. The sense circuit of claim 14, wherein the voltage coupling circuit is further coupled between the first node and the gate of the third transistor, and is further configured to provide a second voltage to the gate of the third transistor, wherein the second voltage is negatively correlated to the common voltage at the first node.

16. The sense circuit of claim 15, wherein the voltage coupling circuit further comprises:
a second capacitor, coupled between the output terminal of the inverter and the gate of the third transistor.

17. The sense circuit of claim 16, wherein the second capacitor comprises a MOS capacitor comprising a fifth transistor, wherein a source of the fifth transistor and a drain of the fifth transistor are coupled to the gate of the third transistor, and a gate of the fifth transistor is coupled to the output terminal of the inverter, and a size of the fifth transistor is equal to a size of the third transistor.

18. The sense circuit of claim 17, wherein a width-to-length ratio of the fourth transistor is greater than or equal to a width-to-length ratio of the fifth transistor.

19. The sense circuit of claim 10, wherein the bias circuit comprises a latch circuit configured to latch voltages of the second node and the third node.

20. A non-volatile memory device, comprising:
a memory array, comprising a plurality of bit lines;
the sense circuit of claim 10; and
a bit line selector, configured to select a set of bit lines from the plurality of bit lines to respectively couple to the plurality of data lines.
